(19) United States
(12) Patent Application Publication
(10) Pub. No.: US 2012/0090868 A1
(43) Pub. Date: Apr. 19, 2012

(54) HOUSING AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); YING-YING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/094,994

(22) Filed: Apr. 27, 2011

(30) Foreign Application Priority Data
Oct. 14, 2010 (CN) 201010508291.7

(51) Int. Cl. H05K 5/00; C23C 14/34; C23C 14/08

(52) U.S. Cl. 174/50; 204/192.15

(57) ABSTRACT

A housing for an electronic device includes a metal substrate and a luminous layer formed on the metal substrate, the luminous layer mainly comprises ZnO mixed with In. The disclosure also described a method to make the housing.

### BACKGROUND

1. Technical Field

The present disclosure relates to housings for electronic devices and a method for making the same.

2. Description of the Related Art

Patterns are typically formed on housings for electronic devices by printing. However, the printed patterns may often present non-changing and tedious appearance without sufficient attractiveness to consumers.

Therefore, there is room for improvement within the art.

### BRIEF DESCRIPTION OF THE DRAWINGS

Many aspects of the present housing of electronic device and method for making the same can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a sectional schematic view of a housing of an electronic device according to an exemplary embodiment.

FIG. 2 is a structural schematic view of a coating machine for fabricating the housing shown in FIG. 1.

### DETAILED DESCRIPTION

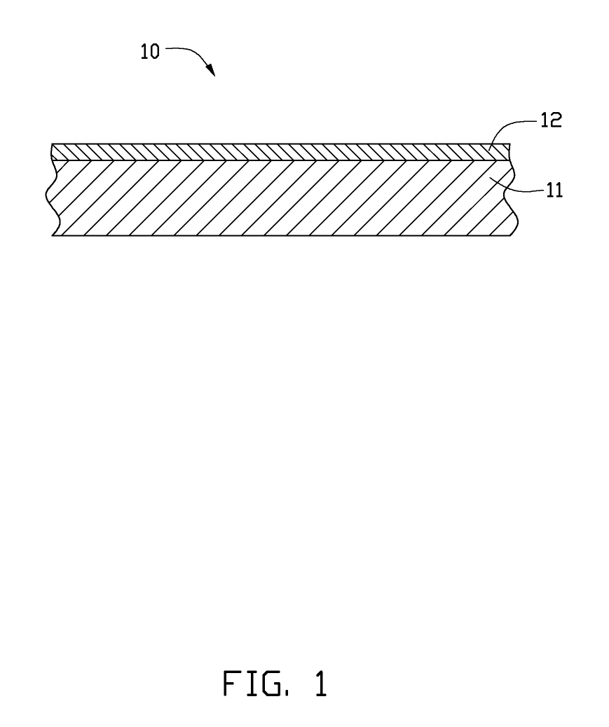

FIG. 1 shows an exemplary embodiment of a housing 100 of an electronic device such as a mobile phone. The housing 100 includes a substrate 11 and a luminous layer 12 formed on the surface of the substrate 11.

The substrate 11 can be substantially made of metal materials such as stainless steel, copper, titanium (Ti), titanium alloy, aluminum, or aluminum alloy. The luminous layer 12 is photoluminescence and substantially comprises zinc oxide (ZnO), mixed with a little indium (In). The luminous layer 12 can further include rare-earth elements such as strontium (Sr), europium (Eu), platinum (Pt). A thickness of the luminous layer 12 is less than about 500 nanometer (nm). The luminous layer 12 can absorb light and accumulate luminous energy in a lit environment. The luminous layer 12 can glow in the dark by releasing luminous energy.

A method of making the housing 10 includes following steps.

The substrate 11 is cleaned by organic solution to clean grease on the surface of the substrate 11. The organic solution can be ethanol, acetone and/or other organic solvents. A common ultrasonic cleaning machine can be used for cleaning the substrate 11.

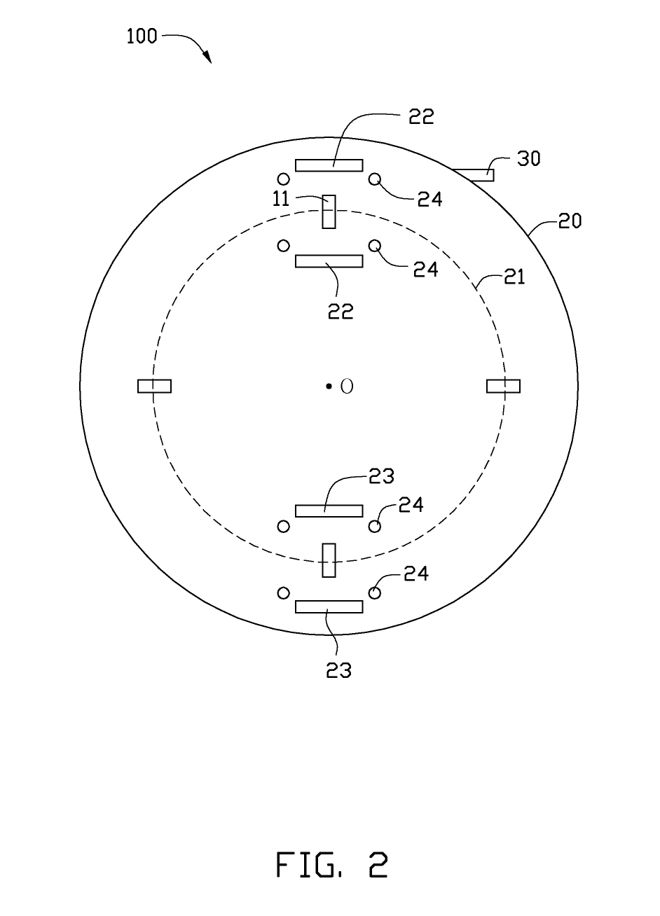

The substrate 11 is plasma cleaned to remove oxide formed on the surface of the substrate 11, to improving the bond of the luminous layer 12 with the substrate 11. Referring to FIG. 2, the substrate 11 can be plasma cleaned by a vacuum sputtering coating machine 100. The vacuum sputtering coating machine 100 includes a sputtering coating chamber 20 and a vacuum pump 30 connecting to the sputtering coating chamber 20. The vacuum pump 30 is used to pump the air out the sputtering coating chamber 20. The vacuum sputtering coating machine 100 further includes a rotating bracket 21, two first targets 22, two second targets 23 and a plurality of gas inlets 24. The rotating bracket 21 rotates the substrate 11 in the sputtering coating chamber 20 relative to the first targets 22 and the second targets 23. The first targets 22 face each other, and are respectively located on opposite sides of the rotating bracket 21. The second targets 23 face each other, and are respectively located on opposite sides of the rotating bracket 21. In this exemplary embodiment, the first targets 22 are Zn/ Zn alloy targets, the Zn alloy can be Zn mixed with one or more rare-earth elements such as Sr, Eu, or Pt. So the rare-earth elements can be formed in the luminous layer 12 The second targets 23 are In targets. Thus, the luminous layer 12 is substantially formed of zinc oxide (ZnO), mixed with a little indium (In) and optionally rare-earth elements. The mixture of rare-earth elements with particles of ZnO improves the conductivity of the particles of ZnO during transition.

To plasma clean the substrate 11, the substrate 11 is placed into the rotating bracket 21. The vacuum level inside the sputtering coating chamber 20 is set to about 3.0*10⁻⁵ Torr. Argon (Ar) is fed into the sputtering coating chamber 20 at a flux between about 300 Standard Cubic Centimeters per Minute (sccm) and about 500 sccm from the gas inlets 24. A bias voltage applied to the substrate 11 may be between about −300 volts (V) and about −500 volts. The Ar particles strike against the surface of the substrate 11, and after about 3 minutes to about 20 minutes, any oxide on the surface of the substrate 11 is removed.

The luminous layer 12 is deposited on the substrate 11. The vacuum level inside the sputtering coating chamber 20 is set to about 3.0*10⁻⁵Torr. The temperature in the sputtering coating chamber 20 is set between about 20° C. (Celsius degree) and about 300° C. A bias voltage applied to the substrate 11 is adjusted to between about −100 volts and about −300 volts. Argon and Oxygen are fed into the sputtering coating chamber 20 from the gas inlets 24, with Argon at a flux between about 150 sccm and about 300 sccm, and Oxygen at a flux between about 10 sccm and about 120 sccm. The first targets 22 in the sputtering coating chamber 20 are evaporated at a power between about 3 kW and about 10 kW. After between about 20 minutes and 60 minutes, a coating layer (not shown) is deposited on the substrate 11. The coating layer mainly includes ZnO. Then, the first targets 22 and the Oxygen are turned off. The second targets 23 are turned on. The sputtering of the second targets 23 lasts about 5 to about 10 minutes, and the In particles are evenly embedded into the coating layer to form the luminous layer 12. Then, the housing 10 is taken out of the vacuum sputtering coating machine 100.

By illuminating in light, the particles of ZnO can transit form a low orbit to a high orbit to accumulate luminous energy. Then eliminating the illumination, the particles of ZnO can reverse to transit from the high orbit to the low orbit to release energy and emit light. When rare-earth elements are mixed with particles of ZnO. the conductivity of the particles of ZnO during transition can be improved and, accordingly enhancing the lighting performance of the ZnO.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A housing of electronic device, comprising:
a metal substrate; and
a luminous layer formed on the metal substrate, the luminous layer substantially comprising ZnO mixed with a little In.

2. The housing of electronic device as claimed in claim 1, wherein the luminous layer further includes at least one rare-earth element.

3. The housing of electronic device as claimed in claim 1, wherein a thickness of the luminous layer is less than about 500 nanometer(nm).

4. The housing of electronic device as claimed in claim 1, wherein the metal substrate is one of stainless steel, copper, titanium, titanium alloy, aluminum, or aluminum alloy.

5. A method for making a housing of electronic device, comprising:
providing a metal substrate; and
forming a luminous layer on the surface of the metal substrate, the luminous layer substantially comprising ZnO mixed with a little In.

6. The method for making a housing of electronic device as claimed in claim 5, wherein further comprising cleaning the metal substrate by organic solution to clean grease before forming the luminous layer.

7. The method for making a housing of electronic device as claimed in claim 5, wherein further comprising plasma cleaning to remove any oxides before forming the luminous layer.

8. The method for making a housing of electronic device as claimed in claim 5, wherein during plasma cleaning, placing the substrate into a chamber of a coating machine, floating argon(Ar) into the chamber, exerting a voltage on the substrate, the Ar particles striking the surface of the substrate to remove any oxides.

9. The method for making a housing of electronic device as claimed in claim 8, wherein during forming the coating, feeding Ar and Oxygen into the chamber and turning on the first targets to sputter ZnO particles to the substrate, then turning off Oxygen and the first targets, turning on the second targets and sputtering In particles combining with ZnO to form the luminous layer.

10. The method for making a housing of electronic device as claimed in claim 9, wherein the first target is made of Zn or Zn alloy.

11. The method for making a housing of electronic device as claimed in claim 9, wherein the Zn alloy is Zn mixed with at least one rare-earth elements.

12. The method for making a housing of electronic device as claimed in claim 9, wherein the second target is made of In.
